(19) United States
(12) Patent Application Publication
(10) Pub. No.: US 2025/0383580 A1
(43) Pub. Date: Dec. 18, 2025

(54) System and Method for Transfer of Signals Between a Cryogenic System and an External Environment

(71) Applicant: QphoX B.V., Delft (NL)

(72) Inventors: Robert Stockill, Delft (NL); Selim Scharmer, Delft (NL); Bas Hensen, Delft (NL); Simon Groeblacher, Delft (NL); Matthew Weaver, Delft (NL); Frederick Hijazi, Delft (NL)

(21) Appl. No.: 18/877,339

(22) PCT Filed: Jun. 21, 2023
(86) PCT No.: PCT/EP2023/066858

§ 371 Date: Dec. 20, 2024

(30) Foreign Application Priority Data
Jun. 21, 2022 (GB) 2209126.8

(51) Int. Cl. G02F 2/00; G06N 10/40; H03H 9/00

(52) U.S. Cl. CPC G02F 2/008; G06N 10/40; H03H 9/0004

(57) ABSTRACT

A system and method for transfer of signals between an inside of a cryogenic system and an external environment including at least one optical source (e.g., a laser) for generating optical input signals and at least one fibre for transferring modulated optical signals to the inside of the cryogenic system and receiving optical output signals from the inside of the cryogenic system. A plurality of detectors, located in the external environment, is used for detecting the optical output signals and are connected to the fibre. A plurality of first transducers converts the modulated optical signals to microwave input signals and a plurality of second transducers converts the microwave input signals to optical output signals. A first microwave impedance matching resonator is connected to the plurality of first transducers and a second microwave impedance matching resonator is connected to the plurality of second transducers.

### CROSS-REFERENCE TO RELATED APPLICATIONS

This application is the United States national phase of International Patent Application No. PCT/EP2023/066858 filed Jun. 21, 2023, and claims priority to United Kingdom Patent Application No. 2209126.8 filed Jun. 21, 2022, the disclosures of each of which are hereby incorporated by reference in their entireties.

### BACKGROUND

### Field of the Invention

The field of the invention relates to a system for transfer of data between an inside of a cryogenic system and an external environment, more specifically to control and/or readout the states of a quantum processor.

### Technical Considerations

Quantum computers are expected to solve complex problems that are intractable on current classical computers. Quantum computers could form a large part of the future high-performance computing market. Many of the candidates for quantum computing, including superconducting qubits and spin qubits, require operation at cryogenic temperatures and microwave frequency driving fields (between hundreds of MHz and several hundreds of GHz). To outpace classical computers, it will be crucial to scale up the number of qubits in quantum computers from the present state of the art of order 100 to order 1000000 and more. Scaling up the number of qubits will require delivery of microwave signals to cryogenic refrigerators and retrieval of microwave signals from cryogenic refrigerators, such as dilution refrigerators and liquid helium systems.

Two challenges with scaling up the number of qubits are the heat load and the space requirements of the signal delivery mechanism as cryostats have limited area on their baseplate and limited cooling capacity.

The standard method for delivery of microwaves signals to a quantum processor of the quantum computer is through coaxial radio frequency (RF) cables with a series of attenuators. One RF cable can deliver microwave signals to drive multiple qubits or qubit readout resonators via time and frequency multiplexing. The qubits are read out by retrieving signals from the cryogenic system or refrigerator (also called cryostat) after amplification at higher temperatures within the cryostat, with one coaxial RF line per multiple qubits.

Delivery and retrieval of microwave signals are further used for several applications related to quantum computing including the powering of amplifiers, displacement of quantum states, magnetic field sensing, and cavity occupation readout. With present approaches for retrieving of microwave signals it is impractical to increase the number of electrical cables in a system to a sufficient scale to support the large numbers of qubits required for practical quantum processors.

An alternative system for delivery and retrieval of the microwave signals based on optical fibres is outlined in this document. The optical fibres are present in telecommunications networks, data centers and supercomputers because optical fibres offer large bandwidth, small form factor and low power dissipation.

Information is usually encoded in certain telecommunication frequency bands because of the low loss through the optical fibres. The advantages of the optical fibres can also be applied to quantum computing systems to improve bandwidth, space requirements, efficiency, and reduce thermal conductivity.

At a small scale, the microwave signals have been delivered into the cryostats via an optical carrier and superconducting qubits have been read out via optical carrier. For example, B. Van Zeghbroeck, “Optical data communication between Josephson-junction circuits and room-temperature electronics,”, IEEE Transactions on Applied Superconductivity, vol. 3, no. 1, Mar. 1993 (DOI: 10.1109/77234002), showed basic connection to and from Josephson junction circuits with photodiodes and laser diodes.

Lecocq et al. “Control and readout of a superconducting qubit using a photonic link”, Nature, 591, 575-579, 2021, (DOI: 10.1038/s41586-021-03268-x), showed that control pulses for both qubit manipulation and readout drive-tones could be delivered to the baseplate of a dilution refrigerator. Lecocq et al. used an electro-optic modulator coupled to an optical fibre passing into the dilution refrigerator and a commercially available fibre-coupled photodiode. In this paper it was proposed that the design could be extended by adding in multiplexing, demultiplexing, and a higher load resistor for the photodiode. Nevertheless, it remains an open question how such a system could be implemented in a scalable way.

One challenge which is outlined by Lecocq et al. is that of power dissipation in the dilution refrigerator. In Lecocq et al. this challenge is proposed to be resolved by the reduced passive power dissipation of the optical fibres with respect to the coaxial RF cables. However, in Lecocq et al., the active power dissipation on the coldest stage of the cryostat exceeds the power dissipation of the coaxial RF cabling if drive pulses are applied for more than 2% of the time per on-off cycle. The excess of the power dissipation of the coaxial RF cabling limits a duty cycle of quantum processors.

The authors of Lecocq et al. propose that this limitation can be overcome by placing a higher load resistor (10 kOhm) at the output of the photodiode. The higher load resistor would decrease power dissipation and Lecocq et al. suggests that the photodiode and the load resistor could be directly connected to the quantum processor, thereby decreasing impedance mismatches. Lecocq et al. states that the distance between the photodiode and the quantum processor should be much less than one centimeter to avoid standing waves. Therefore, from Lecocq et al. one technical problem is known-the distance between the photodiode and the quantum processor has to be small (much less than one centimeter) and has to be chosen precisely in order to decrease impedance mismatches.

However, close proximity of superconducting materials, for example, the superconducting materials used in superconducting qubits, to optical light, can lead to quasiparticle generation and the destruction of the state of qubits (as highlighted by Mirhosseini et al. “Superconducting qubit to optical photon transduction” Nature, vol. 588, 23 Dec. 2020). The close proximity of the superconducting materials could be, for example, an optical chip wirebonded to the superconducting qubit chip or an optical fiber located in a same shielding that can act as a superconducting qubit with direct line of sight to an optical fiber. It would be possible to use longer connections to separate the photodiodes from the quantum processors to avoid the issue of the quasiparticle generation and the destruction of the state of qubits, but the resulting impedance mismatch would also lead to power dissipation.

Another challenge which is outlined in Lecocq et al. is that of shot noise. The authors of Lecocq et al. identify the shot noise as a fundamental limit on the noise produced by the photodiode. Lecocq et al. estimates that, with an increased load resistance, the shot noise would increase and hence a qubit control gate error rate would also increase. For example, Lecocq et al. states that with the 50 Ohm resistor, the error probability due to shot noise is 8*10⁻⁵, but with the 10 kOhm resistor, the error probability would increase to 10-³, which could limit the scalability of the superconducting qubit processors.

US Patent Application No. US 2018/0003753 A1, “Read out of quantum states of microwave frequency qubits with optical frequency photons”, IBM, 2016, proposed using the presence or absence of an optical signal to readout the state of a superconducting qubit. This document outlined a method which includes the possibility of multiplexing but does not allow for the recovery of arbitrary microwave states. Readout of both amplitude and phase quadratures is the more standard method of reading out superconducting qubits.

Delanay et al., “Non-destructive optical readout of a superconducting qubit”, arXiv: 2110.09539, 2021, (DOI: 10.48550/arXiv.2110.09539) showed readout of a superconducting qubit via optical fields including the readout of amplitude and phase of a microwave signal. This approach includes large free space optical cavities (occupying a large volume on the baseplate) and free space rather than fibre transmission out of the dilution refrigerator. However, it is not clear how this approach could be scalably combined with fibers and multiplexed.

International Patent Application No. WO 2022/120469 A1, “Hybrid photonics-solid state quantum computer”, ANYON SYSTEMS INC, details a system which combines sending microwave signals to a quantum processor using optical fibres and/or retrieving the microwave signals back from the quantum processor using the optical fibres. This document uses a similar geometry with multiplexers and signal delivery system as described in Lecocq et al. (see above). In addition, WO 2022/120469 A1 states that an amplifier, such as a Josephson parametric amplifier or a traveling-wave parametric amplifier, could be used to reduce power dissipation, but a delivery of a powerful pump signal to the parametric amplifiers is required in this case.

The delivery of the powerful pump signal to the parametric amplifiers could be performed via additional coaxial cabling with accompanying heat load or with the powerful optical pump signal. It could be challenging to deliver the powerful pump signals without excess power dissipation. For retrieving the microwave signals from the quantum processor, WO 2022/120469 A1 uses microwave to optical transducers and multiplexers to generate the same microwave signal outside the cryostat as the microwave signal that is input inside the cryostat.

An aspect of switching to optical fibres for delivering and retrieving the microwave signals is the low power dissipation which can be realized by this approach. This low power dissipation must also be accompanied by low added noise in the microwave signals delivered to the cryostat. WO 2022/120469 A1 is silent about how to resolve both requirements of the low power dissipation and low added noise. A method resolving these two challenges would significantly improve an optical cryogenic interface.

Another challenge known from WO 2022/120469 A1 is that of detecting the optical signals which are returned from the cryostat. This document does not detail how to derive the phase and amplitude information from the optical signal returned from the cryostat. The phase and the amplitude of the optical signals are the elements obtained from reading out the state of a qubit. Notably, the cryogenic systems are noisy and randomize the phase information in the optical signal. It remains an open challenge how added phase noise of the cryogenic system can be reduced from optical phase noise to an acceptable level for a full reconstruction of the qubit state.

There have been several demonstrations of cryogenically compatible electro-optic modulators. Eltes et al., “An integrated optical modulator operating at cryogenic temperatures”, Nat. Mater. 19, 1164-1168, 2020, (DOI: 10.1038/s41563-020-0725-5) demonstrates an electro-optic switching and modulation from room temperature down to 4K by using the Pockels effect in integrated barium titanate devices.

Yousefi et al. “A cryogenic electro-optic interconnect for superconducting devices”, Nat Electron 4, 326-332, 2021, (DOI: 10.1038/s41928-021-00570-4) demonstrates a cryogenic electro-optical readout of a superconducting electromechanical circuit using a commercial titanium-doped lithium niobate modulator.

Pintus et al. “An integrated magneto-optic modulator for cryogenic applications”, Nat Electron 5, 604-610, 2022, (DOI: 10.1038/s41928-022-00823-w) demonstrates an integrated current-driven modulator that is based on the magneto-optic effect and can operate at temperatures as low as 4 K.

Gehl et al. “Operation of high-speed silicon photonic micro-disk modulators at cryogenic temperatures”, Optica 4, 374-382, 2017, (DOI: 10.1364/OPTICA.4.000374) demonstrates the operation of a high-speed, CMOS compatible silicon micro-disk modulator transmitting data at rates up to 10 Gb/s and at temperatures down to 4.8 K.

Lee et al. “High-performance integrated graphene electro-optic modulator at cryogenic temperature” Nanophotonics, vol. 10, no. 1, 2021, pp. 99-104. (DOI: 10.1515/nanoph-2020-0363) demonstrates an integrated graphene-based electro-optic modulator whose 14.7 GHz bandwidth at 4.9 K exceeds the room temperature bandwidth of 12.6 GHz.

Chakraborty et al. “Cryogenic operation of silicon photonic modulators based on the DC Kerr effect” Optica 7, 1385-1390 (2020), (DOI: 10.1364/OPTICA.403 1 78) shows DC-Kerr-effect-based modulation at a temperature of 5 K at GHz speeds, in a silicon photonic device fabricated exclusively within a CMOS-compatible process.

### SUMMARY

This document discloses a system for transfer of signals between an inside of a cryogenic system and an external environment. The system comprises at least one optical source (e.g., a laser) for generating optical input signals and at least one fibre for transferring modulated optical signals to the inside of the cryogenic system and receiving optical output signals from the inside of the cryogenic system. A plurality of detectors, located in the external environment, is used for detecting the optical output signals and are connected to the at least one fibre. The system also comprises, in the cryogenic system, a plurality of first transducers for converting the modulated optical signals to microwave input signals and a plurality of second transducers for converting the microwave output signals to optical output signals. A first microwave impedance matching resonator is connected to the plurality of first transducers and a second microwave impedance matching resonator is connected to the plurality of second transducers. The first microwave impedance matching resonator and the second microwave impedance matching resonator are, for example, a superconducting microwave frequency resonator. High impedance inputs or high impedance outputs from the first transducer and the second transducer can lead to higher transduction efficiency and lower power dissipation. The first microwave impedance matching resonator and the second microwave impedance matching resonator allow for low-loss connection of the high impedance outputs from the first transducer and the high impedance inputs to the second transducer to channels with a different impedance, for example 50 Ohm resistor line, to enable delivery and retrieval of signals from the cryogenic system.

In a further aspect, the system comprises a plurality of first multiplexers having first multiplexer inputs connected to the plurality of optical sources and first multiplexer outputs connected to the one or more fibres. This enables the fibre(s) to carry multiple optical signals and thus reduces the number of the fibres.

Correspondingly, a plurality of first demultiplexers can be located in the inside of the cryogenic system. The plurality of first demultiplexers has first demultiplexer inputs connected to the at least one fibre and first demultiplexer outputs connected to the plurality of first transducers. The first demultiplexers can separate the optical signals being carried on the fibre.

A plurality of second multiplexers is, in a further aspect, located in the inside of the cryogenic system and have second multiplexer inputs connected to the plurality of second transducers and second multiplexer outputs connected to the at least one fibre. Correspondingly, in the external environment, a plurality of second demultiplexers having second demultiplexer inputs is connected to the at least one fibre and second demultiplexer outputs are connected to the plurality of detectors.

In one aspect, the system further comprises an electro-optic converter configured to modulate the optical input signals. This enables the communication of information into the cryogenic system. The electro-optic converter modulates at least one of the phase, amplitude, or frequency of the optical input signals.

The first superconducting microwave impedance matching resonator and the second superconducting microwave resonator are configured to operate at a temperature below 20 K, and in one aspect, in the milli-Kelvin range.

This document also discloses a method for transfer of signals between an external environment and a cryogenic system. The method comprises generating a plurality of optical input signals, multiplexing and transferring the plurality of modulated optical signals through the optical fibre to the inside of the cryogenic system, converting the plurality of modulated optical signals to microwave input signals and applying the microwave input signals to a set of first microwave impedance matching resonators. The quantum processor is coupled to the first microwave impedance matching resonator which enables transferring of the microwave input signal to the quantum processor to control the state or drive the readout of a set of qubits from the quantum processor.

The method further comprises interacting the microwave input signal with qubits in a quantum processor and thereby forming a microwave output signal output from the quantum processor into a second microwave impedance matching resonator and converting the microwave output signal to the plurality of optical output signals. The plurality of optical output signals is transferred along the optical fibre to the external environment from the cryogenic system and then the amplitude and the phase of the plurality of optical output signals is detected. This enables the determination of the state of the qubit in the quantum processor.

The system and method of this document enables a reduction in the active and passive heat dissipation for the delivery and retrieval of the signals to and from the quantum processor. The use of the optical fibre for the delivery and retrieval of the optical signals enables less heat dissipation than the known RF lines, RF amplifier chains and RF attenuation chains currently used for the transfer of signals.

### BRIEF DESCRIPTION OF THE DRAWINGS

FIG. 1 shows a system for transfer of signals between an inside of a cryogenic system and an external environment.

FIG. 2 shows a correction of the path length of the microwave output signal induced by dephasing from the cryogenic system.

FIG. 3 shows a detailed system for transfer of signals between an inside of a cryogenic system and an external environment and the signal detection in the external environment.

FIG. 4 shows a method for transfer of signals between an external environment and a cryogenic system.

### DETAILED DESCRIPTION

The invention will now be described on the basis of the drawings. It will be understood that the embodiments and aspects of the invention described herein are only examples and do not limit the protective scope of the claims in any way. The invention is defined by the claims and their equivalents. It will be understood that features of one aspect or embodiment of the invention can be combined with a feature of a different aspect or aspects and/or embodiments of the invention.

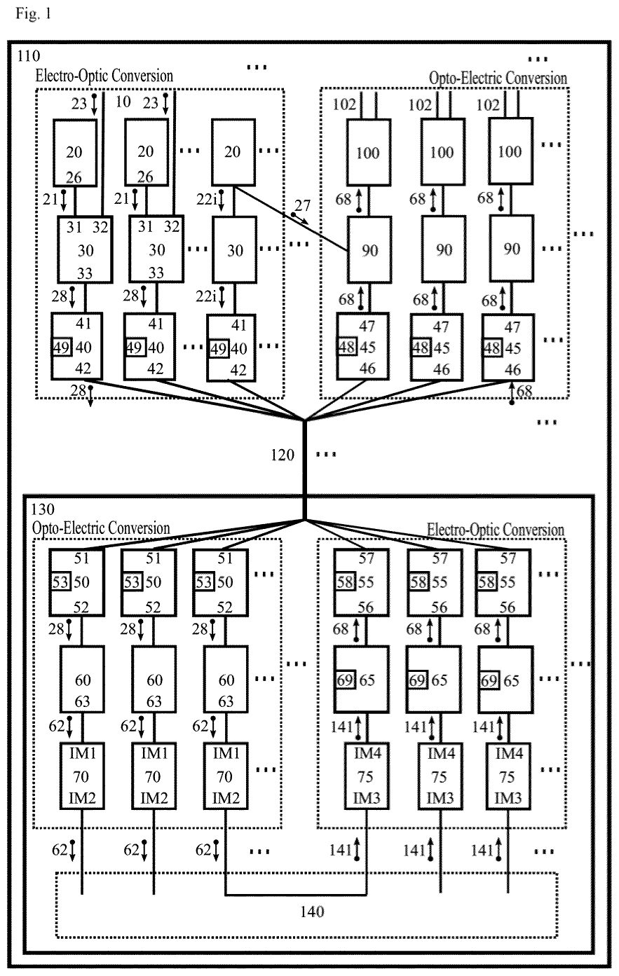

FIG. 1 shows a system 1 for transfer of signals from an input 10 between an inside of a cryogenic system 130 and an external environment 110.

The system 1 comprises at least one laser source 20 which is configured to generate N optical tones 26 in an optical input signal 21. The laser source 20 is, but not limited to, an optical pump, a laser (for example N laser sources 20), a semiconductor laser. The N optical tones 26 can be generated either from the N laser sources 20, or, alternatively through phase modulation and generation of L sidebands using a reduced number of P lasers sources 20. The number P is equal the difference of N and L.

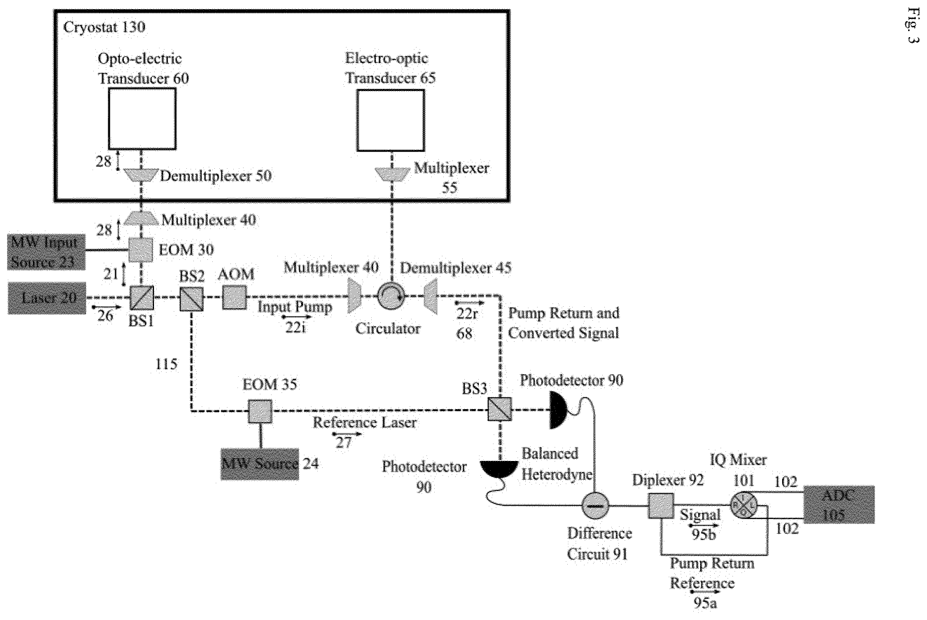

At the output of the laser source(s) 20, the N optical tones 26 are separated into two paths: the optical input signal 21 and an optical pump using, for example, a first beam splitter BS1. A second beam splitter BS2 further divides the optical pump into a pump signal 22i and a reference optical signal 27. The reference optical signal 27 is used for readout and is passed to a second electro-optic modulator 35, as will be explained later with reference to FIG. 3. The optical input signal 21 from the first beam splitter BSI is transferred to an optical input 31 of a first electro-optic modulator 30. The first electro-optic modulator 30 receives input signals 23 (microwave signals) as an input 10 at an electro-optic modulator microwave signal input 32 and uses the electro-optic effect for the modulation of the optical input signals 21 which allows the input signals 23 to modulate the optical tones 26 on the optical input signals 21. The input signals 23 could be generated, for example, by upconverting I input signals and Q input signals at a lower frequency from an arbitrary waveform generator with a first microwave IQ mixer (not shown) using a microwave source 24 as a local oscillator.

The first electro-optic modulator 30 modulates at least one of the phase, amplitude, or frequency of the optical input signal 21 to produce a modulated optical signal 28 at an electro-optic modulator output 33. In an alternative aspect, no first electro-optic modulator 30 is used and the modulation of the optical input signal 21 is carried out at the output of the laser source 20.

The modulated optical signal 28 is coupled to a first multiplexer input 41 of a first multiplexer 40 at which the modulated optical signals 28 are multiplexed into one or more optical fibres 120. The one or more optical fibres 120 are connected to a first multiplexer output 42. The first multiplexer 40 comprises at least one first optical resonator 49 (for example N optical resonators corresponding to the N optical tones 26) coupled to M fibre modes. The M fibre modes are waveguide modes or another spatial mode for light transmission. The M collection modes are directed into the at least one fibre 120. In one aspect of the invention there will be M fibres 120, for example.

It will be appreciated that the first multiplexer 40 is an optional element of the system 1 and that the modulated optical signal 28 can be coupled directly to the optical fibres 120.

The laser source 20, the first electro-optic modulator 30 and the first multiplexer 40 are located in the external environment 110 and generally kept at room temperature.

The optical fibre 120 carries the modulated optical signals 28 through the M optical carriers into the cryogenic system 130. The cryogenic system 130 is a system that operates, for example, at temperatures below 20K and, in one aspect, at millikelvin temperatures.

The optical fibre 120 transmits the modulated optical signal 28 to a first demultiplexer input 51 of at least one first demultiplexer 50. The first demultiplexer 50 can be, but is not limited to, a prism, diffraction gratings, a spectral filter, an optical cavity, such as a whispering gallery mode resonator, Bragg gratings, or a ring resonator. The first demultiplexer 50 separates out the M fibre modes (or optical carriers) carrying the modulated optical signals 28 on the optical fibre 120 and passes the modulated optical signals 28 from a first demultiplexer output 52 to one or more of first transducers 60.

It will be noted that the first demultiplexer 50 is an optional element of the system 1 and the output of the optical fibre 120 could be directly connected to the first transducer 60.

The first transducer 60 is an optoelectronic converter that performs an opto-electric conversion operation to deliver an electrical input signal 62 (for example a microwave input signal 62) at a first transducer output 63 of the first transducer 60. The first transducer 60 converts the modulated optical signals 28 from the M optical fibres 120 to the electrical input signals 62, as will be explained later. The first transducer 60 is, for example, a photodiode (made from e.g., InGaAs, InAsSb), a light detector, a light sensor, or a phototransistor, a microwave-to-optics converter, an opto-piezo-electric device, an electro-optomechanical device, but this list is not intended to be limiting of the invention.

Output electrodes at the first transducer output 63 of the first transducer 60 couple directly or via wire bonds to at least one first microwave impedance matching resonator 70. The first microwave impedance matching resonator 70 is coupled to a device 140 by a waveguide as will be explained later.

In one aspect, the device 140 is a superconducting quantum processor, a quantum sensor or a quantum array.

Outputs of the quantum processor 140 are coupled by a waveguide to at least one second microwave impedance matching resonator 75. The second microwave impedance matching resonator 75 receives a microwave output signal 141 (which has interacted with quantum states) from the quantum processor 140 at a microwave resonator frequency and outputs the microwave output signal 141 representative of the read-out quantum states of the quantum processor 140. The microwave output signal 141 ranges from about 3 GHz to 12 GHz, but this is not limiting of the invention.

The first microwave impedance matching resonator 70 and the second microwave impedance matching resonator 75 can be implemented as superconducting microwave LC resonators.

The second microwave impedance matching resonator 75 is coupled to at least one second transducer 65. The second transducer 65 is, for example, an electro-optic converter that performs an electro-optic conversion operation to deliver an optical output signal 68 at the output of the second transducer 65 representative of the microwave output signal 141 received from the second microwave impedance matching resonator 75. In one aspect, the electro-optic effect is a Pockels effect and in another non-limiting aspect, the conversion of the microwave output signal 141 to the optical output signal 68 uses a piezo-optomechanical effect.

The second transducer 65 is a device selected from a group consisting of an electro-optic device, a microwave-to-optics converter, an opto-mechanical device, an opto-piezo- electric device, an electro-optomechanical device, an electro-optical converter via piezo-optomechanical effect and a magneto-optic device.

The second transducers 65 are coupled optionally to second multiplexer inputs 56 of at least one of a plurality of second multiplexers 55. The optical output signal 68 is addressed to the second multiplexer input 56 of the second multiplexer 55 and the optical output signal 68 is multiplexed out of a second multiplexer output 57 into the at least one optical fibre 120. The second multiplexer 55 comprises at least one third optical resonator 58 coupled to the M optical carriers. The M optical carriers are directed into the at least one optical fibre 120 (M fibres for example).

It will be appreciated that the second multiplexer 55 is an optional element of the system and the optical output signal 68 can be coupled directly to the optical fibre 120.

The same optical fibre 120 can be used for the delivery and the readout of the optical signals to and from the cryogenic system 130. The bandwidth of the optical fibre 120 is sufficient to allow both the modulated optical signal 28 and the optical output signal 68 to propagate through the optical fibre 120 at the same time.

The first demultiplexer 50, the first transducer 60, the first microwave impedance matching resonator 70, the quantum processor 140, the second microwave impedance matching resonator 75, the second transducer 65 and the second multiplexer 55 are located inside the cryogenic system 130 at the cryogenic temperature.

The optical fibre 120 is coupled to a second demultiplexer 45 through a first demultiplexer input 46 located in the external environment 110. The second demultiplexer 45 can be, but not limited to, a prism, diffraction gratings, a spectral filter, optical resonator, ring optical resonator. The second demultiplexer 45 separates the M optical carriers carrying the optical output signal 68 from inside of the cryogenic system 130 and passes the optical output signal 68 from a second demultiplexer output 47 to a detection circuit 100.

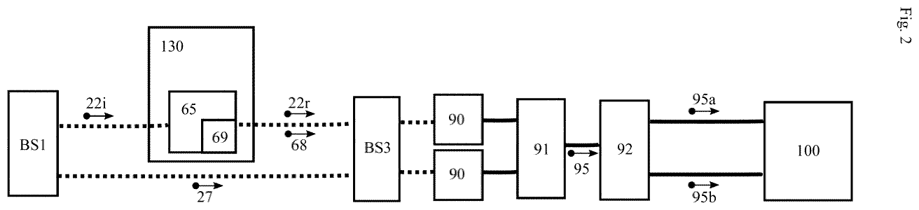

The detection circuit 100 comprises at least one detector 90 that detects the optical output signal 68 from the second transducer 65. The detector 90 is, for example, an optical sensor, a photodiode, a photodetector. The detection circuit 100 will be explained in detail on FIGS. 2 and 3.

The electro-optic conversion inside of the first electro-optic modulator 30 will now be described. This electro-optic conversion can be implemented by two approaches: a modular approach and an integrated approach.

In the modular approach, the optical source 20, the first electro-optic modulator 30 and the first multiplexer 40 are connected together via optical fibres.

In the integrated approach, all of the components (except for the optical source 20) are integrated onto the same chip. An example of the configuration of the integrated approach involves a non-linear optical medium, such as but not limited to a lithium niobate, barium borate, potassium dihydrogen phosphate, potassium titanyl phosphate, integrated on silicon on insulator materials (SOI) stack.

The optical source 20 is coupled into a first waveguide (a ridge waveguide for example) in the non-linear layer. The first waveguide is coupled to a ring resonator waveguide (i.e., first optical resonator 49) patterned into the non-linear layer.

Metallic electrodes are patterned around the first optical resonator 49 such that the application of a voltage changes the resonance frequency of the first optical resonator 49 and modulates the amplitude of the optical input signal 21. The first optical resonator 49 is coupled to a second waveguide which is coupled to multiple ring resonators. The multiple ring resonators are coupled to a third waveguide. In this way the outcoupled light (i.e., the modulated optical signal 28) from the multiple ring resonators is combined and multiplexed.

The third waveguide is coupled into the optical fibre 120 which goes into the cryogenic system 130. The multiplexing is wavelength division multiplexing, but not limited to the given example. It will be appreciated that mode-division multiplexing, dense wavelength division multiplexing, frequency-division multiplexing, time-division multiplexing, and optical time division multiplexing can also be used.

The conversion of the input signals 23 to the modulated optical signals 28 carried in the optical fibre 120 enables many of the modulated optical signals 28 to be transferred through the same optical fibre 120 simultaneously or sequentially. The transfer of the modulated optical signals 28 through the optical fibre 120 allows the system to be more compact and space efficient, and also reduces the heat load.

The output of the optical fibre 120 is coupled in the cryogenic system 130 to the first demultiplexer input 51. The conversion of the optical signals to the electric signals in the cryogenic system 130 will now be described. This opto-electric conversion can be implemented by two approaches: an integrated approach and an on-chip approach.

The integrated approach is a configuration which comprises a silicon on insulator (SOI) substrate with a non-linear (e.g., lithium niobate) top layer. The first optical waveguide and the second optical resonator 53 are patterned to the oxide layer (SiO2) of the silicon on insulator substrate. Electrodes patterned around a lithium niobate layer on top of the SOI substrate enable the tuning of the second optical resonator 53 to match the frequencies at room temperature if necessary.

The second optical waveguide for the second optical resonator 53 couples to the first transducer 60. The first transducer 60 can be an on-chip photodiode junction, silicon, germanium, or gallium arsenide based, for example InGaAs, or a piezo-based opto-mechanical transducer, but this is not limiting of the invention. The first transducer output 63 of the first transducer 60 couples to the input of the first microwave impedance matching resonator 70, the output of which is coupled to a connector for delivery of the microwave input signals 62 to the quantum processor 140. Further detail of the first microwave impedance matching resonator 70 is described in the modular description below.

The modular on chip approach is a configuration which comprises three chips: a first SOI chip (multiplexing/demultiplexing chip) as described above for the demultiplexing of the modulated optical signal 28. The modulated optical signal 28 is coupled out of the output optical ridge waveguides of the first demultiplexer 50 via a coupling element (not shown). The coupling element is, but not limited to, grating couplers, edge couplers, or photonic wire bonds.

The modulated optical signal 28 is coupled to a second chip (transducer chip) of the first transducer 60 via the coupling element. The transducer chip for the first transducer 60 is connected, for example, by wire-bonding, flip-chip, or bump bonding to a third chip (microwave resonator chip) with the first microwave impedance matching resonator 70. The first microwave impedance matching resonator 70 has a first input impedance IM1 and a first output impedance IM2. The value of the first input impedance IM1 may be different than the first output impedance IM2.

Electrodes are patterned onto the first transducer 60 and connect to an optional resistor and the on chip first microwave impedance matching resonator 70. In the case of a photodiode (first transducer 60), the value of the resistor can be larger than the value of the output impedance of the first microwave impedance matching resonator 70 to reduce photocurrent and hence to reduce power dissipation.

The output of the first microwave impedance matching resonator 70 is wire-bonded to a connector for delivery of the microwave input signals 62 to the quantum processor 140. The connection could be a coaxial cable or a microwave connection with higher inductance, but this connection is not limiting of the invention.

The matching of the first input impedance IMI and the first output impedance IM2 of the first microwave impedance matching resonator 70 with a source impedance of the first transducer output 63 and a load impedance of the input to the quantum processor 140 enables the reduction of power dissipation. The first input impedance IMI can be from 1 Ohm to 10 000 000 Ohms and, in one particular example, from 10 Ohm to 10 000 000 Ohm. The first output impedance IM2 can be from 10 Ohms to 1 kOhm, in one non-limiting example, and the first output impedance IM2 can be from 10 Ohms to 377 Ohms. In one aspect, the first output impedance IM2 is 50 Ohm, but this is not limiting of the invention.

In one aspect, a flexible system is created which can impedance match to the inputs of the quantum processor 140. It will be appreciated that a high impedance at the first transducer output 63 or other optoelectronic converter will minimize the power dissipation. This mismatch between the first transducer output 63 and the inputs of the quantum processor 140 can be bridged with the first microwave impedance matching resonator 70.

Using a higher load resistance at the first transducer output 63 increases the voltage for the same photocurrent generated with the same optical power. Therefore, the microwave to optical conversion efficiency is higher for larger load resistances and the power dissipation in delivering the microwave input signal 62 is decreased. However, directly coupling the higher load resistance to a 50 Ohm line will cause reflections and reduce power delivery, but the 50 Ohm line is convenient for modular connections inside the cryogenic system 130.

The use of the first microwave impedance matching resonator 70 enables using a higher resistance at the first transducer 60 and a lower impedance connecting channel to the microwave output at, for example, the quantum processor 140.

When the modulated optical signals 28 are coupled to the first transducer 60, the first transducer 60 outputs a shot noise current. The shot noise current is typically “white” or spectrally flat up to the bandwidth limit of the first transducer 60. The shot noise is not a limiting aspect of the invention and other implementations of the first transducer 60 could output other noise currents in addition to the shot noise current, for example due to the thermal noise in the transducer.

One feature of the first impedance matching resonator 70 is that the first impedance matching resonator 70 transmits one range of frequencies and reflects or dissipates another range of frequencies. Therefore, the first impedance matching resonator 70 can filter out frequencies from the transmitted signals (e.g., microwave input signal 62).

By matching the first microwave impedance matching resonator 70 frequency to the frequency of the microwave input signal 62, the bandwidth of the added noise from the first transducer 60 bandwidth can be reduced. By reducing the bandwidth of the added noise from the first transducer 60 to the bandwidth of the first microwave impedance matching resonator 70,

the total added shot noise from the first transducer 60 can also be reduced. It will be appreciated that a higher resistance of the first transducer output 63 will generate a lower photocurrent for the same amount of the output voltage. Therefore, the ratio between the shot noise current and the signal current will be larger. The larger ratio increases the fraction of the shot noise and the microwave output power. Configuration of the first microwave impedance matching resonator 70 allows to tune to an optimum middle point between low power dissipation and high signal to noise ratio of the output signal (e.g., microwave input signal 62). The optimum value of the first input impedance IMI of the first microwave impedance matching resonator 70 will depend on the power dissipation and noise requirements of the specific application.

One implementation will be described as follows. The output electrodes of the first transducer 60 couple directly or via wire bonds to the first microwave impedance matching resonator 70. The first microwave impedance matching resonator 70 can be, for example, a superconducting spiral nanowire, a meander, or a looped nanowire. By patterning holes of the spiral or a looped nanowire within the wire path, the first microwave impedance matching resonator 70 could also be tuned in frequency via an applied magnetic field.

The first microwave impedance matching resonator 70 connects to an external connector. The external connector can then be attached to microwave cables of variable lengths for convenient delivery of the electrical input signals 62 in the form of microwaves to different parts of the quantum processor 140.

According to a fourth example of the method implementation, a 500 Ohm resistor is placed at the first transducer output 63. The 500 Ohm resistor is coupled to the first microwave impedance matching resonator 70. The first microwave impedance matching resonator 70 is capacitively, inductively or galvanically coupled to the first transducer subcircuit and also to the 50 Ohm resistor line.

If the first microwave impedance matching resonator 70 comprises a superconducting material, the losses in the first microwave impedance matching resonator 70 can be made very small and hence the quality factor can be very large. Because of the large impedance at the first transducer output 63 the voltage generated is IO times larger than the voltage generated in the case of the 50 Ohm resistor without an impedance matching resonator used.

The increase of the voltage in this case corresponds to a reduction of a factor 3.2 in the optical power required to drive the microwave input signal 62. Another advantage of this implementation is that the shot noise bandwidth output from the first microwave impedance matching resonator 70 is decreased compared to the 50 Ohm resonator case.

The bandwidth of the first transducer 60 could be, for example, between 300 MHz and 40 GHz. The reduced noise bandwidth output could be, for example, between 3 MHz and 1 G Hz with a resonator quality factor of 100. The reduced shot noise level and bandwidth will result in higher fidelity qubit control.

According to a fifth example of the method implementation a 50 kOhm resistor is placed at the first transducer output 63. The 50 kOhm resistor is coupled to the first microwave impedance matching resonator 70. The output of the first microwave impedance matching resonator 70 connects to a microwave cable with 50 Ohm impedance.

Because of the large impedance at the first transducer output 63, the voltage generated is 1000 times larger than for the case of the 50 Ohm resistor and no impedance resonator. This difference corresponds to a reduction of a factor 32 in the optical power required to drive the microwave input signal 62. Another advantage of the 50 kOhm resistor is that the shot noise bandwidth output from the first microwave impedance matching resonator 70 is decreased compared to the 50 Ohm resistor case.

The bandwidth of the first transducer 60 could be, for example, between 300 MHz and 40 GHz. The reduced noise bandwidth output could be, for example, between 9 MHz and 3 GHz with the resonator quality factor of 32.

By using a plurality of multiplexed lines in parallel, a much larger number of the electrical input signals 62 can be delivered into the cryogenic system 130.

According to a sixth example of the method implementation, a 1 Ohm resistor is placed at the first transducer output 63. The 1 Ohm resistor is coupled to the first microwave impedance matching resonator 70. The output of the first impedance matching resonator 70 couples to the microwave cable with the 50 Ohm impedance. Because of the smaller resistance at the first transducer output 63, the current for a given voltage is 50 times larger than for the case of a 50 Ohm resistor and without impedance resonator used.

Therefore, the shot noise current at the input of the first microwave impedance matching resonator 70 is about 2.7 times larger than for the case of the 50 Ohm resistor. However, the shot noise power is about seven times smaller than for the case of the 50 Ohm resistor due to the decreased resistance. Another advantage of this implementation is that the shot noise bandwidth output from the microwave impedance matching resonator 70 is decreased compared to the 50 Ohm resistor case.

The bandwidth of the first transducer 60 could be, for example, between 300 MHz and 40 GHz with the resonator quality factor of 7. The reduced noise bandwidth output could be, for example, between 43 MHz and 15 GHz. The reduced shot noise level and bandwidth will result in higher fidelity qubit control gate error.

The retrieving of the amplitude and the phase of microwave signals from N microwave channels inside the cryogenic system 130 will now be described. The use of the second transducer 65 in conjunction with the optical fibre 120 eliminates the need for traveling wave parametric amplifiers or high electron mobility transistors on the baseplate or at higher temperatures inside the cryogenic system 130. The use of the optical fibre(s) 120 also eliminates the need for a plurality of RF cables, auxiliary amplifier cables and a plurality of microwave filters to filter out room temperature noise.

One of the applications for the microwave output signal 141 from the cryogenic system 130 is for qubit readout, but this is not limiting aspect of the invention, and the signal readout could also be used for spectroscopic characterization or as a local power meter.

Cryogenic microwave output retrieval via the optical fibre 120 comprises three stages: converting the N microwave output signals 141 into the N optical output signals 68 in the M optical fibres 120 using a reference signal, passing the M optical fibres 120 out of the cryogenic system 130, and outputting the amplitude and phase of the N optical output signals 68 via referencing to a local oscillator.

In the cryogenic system 130, the N microwave output signals 141 are routed to the N second microwave impedance matching resonators 75. The N second microwave impedance matching resonators 75 match the impedance of the second transducer 65 to the impedance of the input lines of the second microwave impedance matching resonators 75.

The N second transducers 65 convert the N microwave output signals 141 to the N optical output signals 68 imprinted as a modulation of the N optical tones 26. The N optical output signals 68 are routed to N third optical resonators 58 which are coupled to the M output optical fibres 120.

No or only few RF lines, RF amplifiers or RF attenuators are required to connect the cryogenic system 130 to the external environment 110. It will be appreciated that there will be many RF lines within the cryogenic system 130.

The second transducers 65 are, in one aspect, acousto-optic actuators and are made from a piezoelectric on SOI materials stack. The piezoelectric on SOI stack can be, but is not limited to, lithium niobate, aluminum nitride, barium titanate. The microwave inputs of the second transducers 65 are coupled to the N second microwave impedance matching resonators 75 which can have an internal ladder for magnetic field tuning. The N second microwave impedance matching resonators 75 enable matching of a low output impedance of the source (from the qubit readout resonator and 50 Ohm waveguide) with a higher input impedance of the second transducer 65.

The higher input impedance of the second transducer 65 could be needed for impedance matching to the acoustic or optical resonance of the second transducer 65, which may be, for example, 5 kOhm. This high input impedance could allow for a large transduction bandwidth and a high transduction efficiency.

The second input impedance IM3 can be from 10 to 1 kOhm. The second output impedance IM4 can be from 1 Ohm to 10 000 000 Ohm. In one aspect, the second input impedance IM3 is 50 Ohm, but this is not limiting of the invention.

The second transducers 65 transduce the microwave output signal 141 into acoustic signals. The acoustic signals are coupled to a second transducer optical cavity 69 (i.e., an optomechanical cavity) which transduces the acoustic signals to the optical output signals 68 provided that the optical pump signal 22i is input into the second transducer optical cavity 69 at a frequency different than the optical cavity resonance frequency. The second transducer optical cavity 69 is fabricated, for example, on a suspended silicon layer. The pump signal 22i comes from the pump laser sources 20 via the second demultiplexer 45 in the external environment 110 and the second multiplexer 55 in the cryostat 130. In one non-limiting example, the optical tone 26 can be used as the pump signal 22i and can be delivered via the first multiplexer 40 in the external environment 110 to the second multiplexer 55 in the cryostat 130.

The optomechanical cavities either couple directly to Mon-chip silicon waveguides or couple to the N third optical resonators 58 (e.g., optical ring resonators). The N third optical resonators 58 are coupled to the Mon-chip silicon waveguides. The Mon-chip silicon waveguides are then coupled to the M optical fibres 120 which go out of the cryogenic system 130 to the external environment 110.

One of the challenges of converting microwave signals to an optical signal and back to a microwave signal is phase stability. Because of the short wavelength of the optical output signals 68, fluctuations in the length of the fibres driven by the cryogenic system 130 can de-phase the carried microwave output signal 141. Therefore, the phase accrued in the optical fibres 120 must be either passively stable or actively tracked.

FIGS. 2 and 3 illustrate the correction of the path length of the optical output signal 68 induced by fluctuations from the cryogenic system 130.

The laser source 20 produces a laser pump signal 22i which is transferred into the cryogenic system 130 and is incident on the electro-optic converter (i.e., the second transducer 65 with the second transducer optical cavity 69) in the cryogenic system 130 to read out the phase and amplitude of the microwave output signal 141. This laser pump signal 22i can be derived from the laser sources 20 or be generated separately.

The second transducer 65 outputs a portion 22r (return pump signal) of the pump signal 22i and an optical converted signal (optical output signal 68) which is detuned from the pump frequency by the frequency of the microwave output signal 141.

The return pump signal 22r can be obtained by collecting reflection signals or transmission signals from the second transducer optical cavity 69 in the second transducer 65. The amplitude of the microwave output signal 141 is imprinted on the amplitude of the optical output signal 68 (optical converted signal) and the phase of the microwave output signal 141 is imprinted on the difference in phase between the returned pump signal 22r and the converted optical output signal 68.

The optical output signal 68 and the returned pump signal 22r are transmitted by the M optical fibers 120 from the cryogenic system 130 to N fourth optical resonators 48 of the second demultiplexer 45 at room temperature in the external environment 110. The optical resonance frequency matches the optical resonance frequency of the third optical resonators 58 inside the cryogenic system 130. The second demultiplexer 45 outputs the optical output signal 68.

Since the returned pump signal 22r and the optical output signal 68 travel the same optical path, any differences in optical path length are cancelled out.

The returned pump signal 22r and the optical output signal 68 are interfered with the reference optical signal 27 on a third beam splitter BS3. The reference optical signal 27 follows another reference path 115 in the external environment 110.

The first branch of the second beam splitter BS2 generates the pump signal 22i which can be pulsed, or frequency shifted with an acousto-optic modulator AOM. The AOMs are configured for maximum extinction by collecting the optical output signal which is frequency shifted by a given drive frequency. The drive frequency is in the range of 1 MHz to 1 GHZ, but this is not limiting aspect of the invention. The second branch (i.e., the reference path 115) of the second beam splitter BS2 carries the reference optical signal 27 that is directed to the second electro-optic modulator 35 (shown in FIG. 3). The second electro-optic modulator 35 is connected to the microwave source 24. The second electro-optic modulator 35 modulates the amplitude and the frequency of the reference optical signal 27 at a microwave frequency.

The reference optical signal 27 has a known frequency and known amplitude and is used to extract the amplitude and phase of the optical output signal 68 by comparing the phase of the optical output signal 68 with the reference optical signal 27 in the detection circuit 100. The amplitude and phase of the returned pump signal 22r are measured in the same way.

The detector 90 produces two balanced electrical signals 95 with different frequencies corresponding to the frequency of the optical output signal 68 and the frequency of the returned pump signal 22r. The two balanced electrical signals 95 are derived from the optical output signal 68. The frequency of the balanced electrical signals 95 has a different frequency from the frequency of the microwave output signal 141. This frequency shift between the balanced electrical signals 95 and the optical output signal 68 could be due to the frequency shift which the AOM transmits on the pump signal 22i.

With the detection circuit 100, the amplitude of the optical output signal 68 and the phase difference between the two balanced electrical signals 95 can be measured.

In this way the detection circuit 100 reads out the amplitude and phase quadrature of the microwave output signal 141 without significant phase noise. The amplitude and the phase quadrature of the microwave output signal 141 can then be output at room temperature in the external environment 110. Two detection approaches can be used for detection of the reference optical signal 27 and the optical output signal 68.

In a first approach, the second electro-optic modulator 35 modulates the reference optical signal 27 with a drive signal from the microwave source 24. This microwave source 24 could be the same microwave source 24 which is used to generate the input signal 23, but this is not limiting of the invention. By modulating the reference optical signal 27, the second electro-optic modulator 35 adds one or more sidebands at a different optical frequency. The one or more sidebands added to the reference optical signal 27 are separated in frequency from the original reference optical signal 27 by the drive frequency.

The drive frequency of the drive signal could be, for example, between 300 MHz and 100 GHz. The reference optical signal 27 interferes with the optical output signal 68 on the third beam splitter BS3 and is detected with the detectors 90. At least two balanced electrical signals 95 can be produced at the detectors 90.

A first balanced electrical signals 95a has a frequency equal to the difference in frequency between the returned pump signal 22r and the reference optical signal 27. The frequency of the first balanced electrical signals 95a is therefore equal to the drive frequency of the AOM, which is typically a radio frequency, for example in the frequency range between 1 MHz and 1 GHz.

A second balanced electrical signal 95b has a lower frequency than the microwave output signal 141. The frequency of the second balanced electrical signal 95b is equal to the difference in frequency between the generated sideband added to the reference optical signal 27 and the optical output signal 68. The lower frequency of the second balanced electrical signal 95b could be a radio frequency, for example in the range between 1 MHz and 1 GHz. Other balanced electrical signals 95 at different frequencies can also be produced. The different frequencies of the other balanced electrical signals 95 can be due to combinations of different laser frequencies. However, the other different frequencies can be filtered out with a spectral filtering. The spectral filtering could be done, for example, by choosing the detectors 90 with a bandwidth smaller than the drive frequency from the microwave source 24 and smaller than the bandwidth of the microwave output signal 141.

The detection circuit 100 measures the phase difference between the two balanced electrical signals 95 and the amplitude of the two balanced electrical signals 95. The detection of the two balanced electrical signals 95 can be easier because the balanced electrical signals 95 are lower in frequency than the original microwave output signal 141.

The frequencies of the balanced electrical signals 95 can be easier to detect, because the balanced electrical signals 95 have the frequency bandwidth of an analog-to-digital converter 105. In addition, typical microwave detection of the balanced electrical signals 95 involves down converting of a microwave circuit frequency to lower frequencies before electrical detection with, for example, the analog-to-digital converter 105. In this aspect of the invention, the lower frequencies are generated in the optical domain before the detectors 90. Because the two signals 95 are at a lower frequency, detectors 90 with lower bandwidth can be used, which could be more efficient and add less noise. Furthermore, the use of lower frequencies in the detection circuit 100 and the absence of a mixer could reduce the noise of the detection circuit 100.

In a second approach, the second electro-optic modulator 35 is not present in the system or the second electro-optic modulator 35 does not modulate the reference optical signal 27. The reference optical signal 27 interferes with the optical output signal 68 on the third beam splitter BS3 and is detected with the detectors 90.

Therefore, the at least two balanced electrical signals 95a and 95b can be produced. The first balanced electrical signal 95a has a frequency equal to the difference in frequency between the returned pump signal 22r and the reference optical signal 27. The frequency of the first balanced electrical signal 95a is equal to the drive frequency of the AOM, which is typically a radio frequency, for example in the frequency range between 1 MHz and 1 GHz. The second balanced electrical signal 95b has a higher frequency than the first balanced electrical signal 95a. The frequency of the second balanced electrical signal 95b is equal to the difference in frequency between the reference optical signal 27 and the optical output signal 68.

The first balanced electrical signal 95a and the second balanced electrical signal 95b can be separated with a diplexer 92 and the higher frequency component can be down converted to the lower frequency by mixing with a local oscillator (not shown). This local oscillator could be derived from the same microwave source 24 which is used to generate the input signal 23, but this is not limiting of the invention.

This lower frequency could be a radio frequency, for example in the range between 1 MHz and 1 GHz. The frequencies of the two balanced electrical signals 95a and 95b could be easier to detect, because the frequencies of the two balanced electrical signals 95a and 95b are lower than the frequency bandwidth of the analog-to-digital converters 105.

An example of implementation for the room temperature stage is shown in FIG. 3 and uses the M second demultiplexers 45 which are frequency matched to the N third optical resonators 58 in the cryogenic system 130. The M second demultiplexers 45 are configured to separate out the N optical output signals 68 from the optical fibre 120 into N output optical fibres (not shown) connected to the second demultiplexer outputs 47.

Each of the N output optical fibres has the optical output signal 68 and the returned pump signal 22r separated by the microwave output signal frequency 141. The optical output signal 68 and the returned pump signal 22r are interfered with the reference optical signal 27 on the third beam splitter BS3. The optical output signal 68 and the returned pump signal 22r are measured on the at least one detector 90 (two detectors for example, in a balanced heterodyne configuration using the reference optical signal 27 as a local oscillator).

The measured signals from the two detectors 90 are subtracted on a difference circuit element 91. Two signals form the balanced electrical signal 95 contain the optical output signal 68 and the pump return signal 22r which are separated with the diplexer 92.

The second balanced electrical signal 95b, which is derived from the electrical output signal 68, is mixed with a microwave local oscillator reference (not shown on the drawings) and then mixed with the first balanced electrical signal 95a, which is derived from the pump return reference optical signal 27, on an IQ mixer 101 to produce one or two output signals 102 which carry the phase and amplitude information of the microwave output pulse 141.

The output signals 102 could be measured directly or used to reconstruct the microwave output pulse 141 coming from the quantum processor 140 at room temperature using the second microwave IQ mixer (not shown). The output signals 102 are coupled to the analog-to-digital converter 105. The analog-to digital converter (ADC) 105 is configured to convert the output signals 102 to the digital signal.

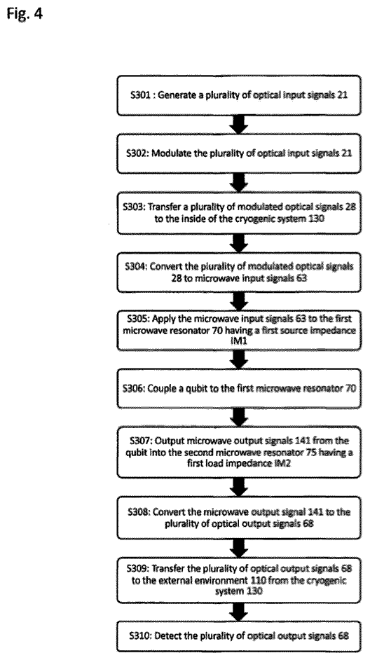

FIG. 4 shows a flow diagram for the method for transfer of signals between the external environment 110 and the cryogenic system 130.

In step S301, the plurality of optical input signals 21 are generated, for example by the laser source 20. The plurality of optical input signals 21 are passed to the first electro-optic modulator 30 and in step S302 are modulated. As noted above, the optical input signals 21 can alternatively be directly modulated inside the laser source 20. The first electro-optic modulator 30 outputs the modulated optical signals 28.

In step S303, the modulated optical signals 28 are transferred to the inside of the cryogenic system 130. The modulated optical signals 28 can be multiplexed by the first multiplexer 40 and can be transferred to the cryogenic system 130 through the optical fibres 120.

In step S304, the modulated optical signals 28 are converted to the microwave input signals 62. The modulated optical signals 28 can be received by the first demultiplexer 50 to separate the modulated optical signals 28 into the different lines. The modulated optical signals 28 can be directed to the first transducer 60.

In step S305, the microwave input signals 62 are applied to the first impedance matching microwave resonator 70.

In step S306, the quantum processor 140 with the qubits is coupled to the first microwave impedance matching resonator 70 and the microwave input signals 62 are transferred to the quantum processor 140.

In step S307, the microwave output signal 141 is output from the quantum processor 140 into the second microwave impedance matching resonator 75.

In step S308, the microwave output signals 141 are converted to the plurality of optical output signals 68. The microwave output signals 141 are converted by the second transducer 65, for example.

In step S309, the optical output signals 68 are transferred to the external environment 110 from the cryogenic system 130. The optical output signals 68 can be multiplexed on the second multiplexer 55 and to be directed to the optical fibres 120. In step S310, the phase and amplitude of the optical output signals 68 are detected by the detectors 90. The detection of the phase and the amplitude can be done by generating two signals: one signal is derived from the return pump signal 22r and another signal is derived from the optical output signals 68. Neither of the generated signals has the frequency of the microwave output signal 141, but the phase of the optical output signal 68 can be reconstructed from the phase difference between the two generated signals. The optical output signals 68 are coupled from the optical fibres 120 to the second demultiplexer 45.

### REFERENCE NUMERALS

1—System
10—Input
20—Laser source
21—Optical input signal
22i—Pump signal
22r—Return pump signal
23—Input signal
24—Microwave source
26—Optical tone
27—Reference optical signal
28—Modulated optical signal
30—First electro-optical modulator
31—Electro-optic modulator optical input
32—Electro-optic modulator microwave signal input
33—Electro-optic modulator output
35—Second electro-optic modulator
40—First Multiplexer
41—First multiplexer input
42—First multiplexer output
45—Second demultiplexer
46—Second demultiplexer input
47—Second demultiplexer output
48—Fourth optical resonator
49—First optical resonator
50—First demultiplexer
51—First demultiplexer input
52—First demultiplexer output
53—Second optical resonator
55—Second multiplexer
56—Second multiplexer input
57—Second multiplexer output
58—Third optical resonator
60—First transducer
62—Microwave input signal
63—First transducer output
65—Second transducer
68—Optical output signal
69—Second transducer optical cavity
70—First microwave impedance matching resonator
75—Second microwave impedance matching resonator
76—Electrical output signal
90—Detector
91—Difference circuit element
92—Diplexer
95—Balanced electrical signal
95a—First balanced electrical signal
95b—Second balanced electrical signal
100—Detection circuit
101—IQ mixer
102—Output signals
105—Analog-to-digital converter
110—External environment
115—Reference path
120—Optical fibre
130—Cryogenic system
140—Quantum processor
141—Microwave output signal
IM1—First input impedance
IM2—First output impedance
IM3—Second input impedance
IM4—Second output impedance
BS1—First beam splitter
BS2—Second beam splitter
BS3—Third beam splitter
AOM—Acousto-optic modulator

1. A system for transfer of signals between an inside of a cryogenic system and an external environment, comprising:
at least one optical source for generating optical input signals;
at least one fiber for transferring modulated optical signals to the inside of the cryogenic system and receiving optical output signals from the inside of the cryogenic system, wherein the modulated optical signals are obtained from modulating the optical input signals;
a plurality of detectors for detecting the optical output signals and being connected to the at least one fiber;
a plurality of first transducers for converting the modulated optical signals to microwave input signals;
a plurality of second transducers for converting microwave output signals to the optical output signals;
a plurality of first microwave impedance matching resonators connected to the plurality of first transducers and coupled to a device for transferring the microwave input signals to the device; and
a plurality of second microwave impedance matching resonators connected to the plurality of second transducers and coupled to the device for obtaining the microwave output signals from the device.

2. The system of claim 1, further comprising a plurality of first multiplexers having first multiplexer inputs connected to the plurality of optical sources and first multiplexer outputs connected to the at least one fiber.

3. The system of claim 1, further comprising a plurality of first demultiplexers located in the inside of the cryogenic system having first demultiplexer inputs connected to the at least one fiber and first demultiplexer outputs connected to the plurality of first transducers.

4. The system of claim 1, further comprising a plurality of second multiplexers located in the inside of the cryogenic system having second multiplexer inputs connected to the plurality of second transducers and second multiplexer outputs connected to the at least one fiber.

5. The system of claim 1, further comprising a plurality of second demultiplexers having first demultiplexer inputs connected the at least one fiber and second demultiplexer outputs connected to the plurality of detectors.

6. The system of claim 1, further comprising a first electro-optic modulator configured to modulate the optical input signals.

7. The system of claim 6, wherein the first electro-optic modulator modulates at least one of a phase, an amplitude, a frequency, or any combination thereof of the optical input signals.

8. The system of claim 1, wherein the plurality of first microwave impedance matching resonators and the plurality of second microwave impedance matching resonators are configured to operate at a temperature below 20 K.

9. The system of claim 1, wherein the opto-electric and electro-optic conversions of the signals are located in the cryogenic system.

10. The system of claim 1, wherein a first input impedance of one of the plurality of first microwave impedance matching resonators ranges from about 1 to 10,000,000 Ohm.

11. The system of claim 1, wherein a first output impedance of one of the plurality of first microwave impedance matching resonators ranges from about 10 Ohm to 1 kOhm.

12. The system of claim 1, wherein a second input impedance of one of the plurality of second microwave impedance matching resonators ranges from about 10 Ohm to 1 kOhm.

13. The system of claim 1, wherein a second output impedance of one of the plurality of second microwave impedance matching as resonators ranges from about 1 to 10,000,000 Ohm.

14. The system of claim 1, wherein the optical source comprises a laser.

15. The system of claim 1, where one of the plurality of first microwave impedance matching resonators and the plurality of second microwave impedance matching resonators are implemented as a superconducting microwave LC resonator.

16. The system of claim 1, wherein amplitude and/or phase of a cryogenic microwave output signal are measured by detecting a returned pump signal and the optical output signal on one or more detectors.

17. A method for transfer of signals between an external environment and a cryogenic system, comprising:
generating a plurality of optical input signals;
transferring a plurality of modulated optical signals to the inside of the cryogenic system by at least one fiber, wherein the plurality of modulated optical signals are obtained from modulating the plurality of optical input signals;
converting the plurality of modulated optical signals to microwave input signals;
applying the microwave input signals to a first microwave impedance matching resonator;
coupling a device to the first microwave impedance matching resonator and transferring the microwave input signals to the device;
outputting a microwave output signal, from the device into a second microwave impedance matching resonator;
converting the microwave output signal to the plurality of optical output signals;
transferring the plurality of optical output signals to the external environment from the cryogenic system by the at least one fiber; and detecting the amplitude and phase of the plurality of optical output signals.

18. The method of claim 17, wherein the device comprises at least one of: a quantum processor, a quantum sensor, a quantum array, or any combination thereof.

19. The method of claim 18, wherein the transferring of a microwave input signal to the quantum processor and the detection of the amplitude and phase of the optical output signal is used to determine the state of a qubit in the quantum processor.

20. A method for transfer of signals from an external environment to a cryogenic system, comprising:
generating a plurality of optical input signals;
transferring a plurality of modulated optical signals to the inside of the cryogenic system by at least one fiber, wherein the modulated optical signals are obtained from modulating the optical input signals;
converting the plurality of modulated optical signals to microwave input signals;
applying the microwave input signals to a first microwave impedance matching resonator; and
coupling a device to the first microwave impedance matching resonator and transferring the microwave input signals to the device.

21. A method for transfer of signals from a cryogenic system to an external environment, comprising:
outputting a microwave output signal from a device into a second microwave impedance matching resonator;
converting the microwave output signal to a plurality of optical output signals;
transferring the plurality of optical output signals to the external environment from the cryogenic system by at least one fiber; and
detecting amplitude and phase of the plurality of optical output signals.
